(19) United States
(12) Patent Application Publication
(10) Pub. No.: US 2023/0369350 A1
(43) Pub. Date: Nov. 16, 2023

(54) DISPLAY DEVICE

(71) Applicant: Samsung Display Co., LTD., Yongin-si, Gyeonggi-do (KR)

(72) Inventors: Hyun Ae PARK, Yongin-si (KR); Kyoung Jin PARK, Yongin-si (KR)

(73) Assignee: Samsung Display Co., LTD., Yongin-si, Gyeonggi-do (KR)

(21) Appl. No.: 18/315,617

(22) Filed: May 11, 2023

(30) Foreign Application Priority Data
May 12, 2022 (KR) 10-2022-0058543

(51) Int. Cl. H01L 27/12; G09G 3/3233; H01L 25/16

(52) U.S. Cl. CPC H01L 27/124; G09G 3/3233; H01L 25/167; G09G 2300/0819; G09G 2300/0842; G09G 2320/0233

(57) ABSTRACT

A display device includes: a substrate; a semiconductor layer disposed on the substrate; a gate conductive layer disposed on the semiconductor layer; and a first data conductive layer disposed on the gate conductive layer, wherein the gate conductive layer includes a first scan line and a light emitting control line extending along a first direction, and a first gate electrode disposed between the first scan line and the light emitting control line in a plan view, the first data conductive layer includes a first connecting member overlapping the first gate electrode, the first connecting member includes a recessed opening and a hole opening, and a part of the hole opening is disposed between the first gate electrode and the light emitting control line in a plan view.

### CROSS-REFERENCE TO RELATED APPLICATION(S)

This application claims priority to and benefits of Korean Patent Application No. 10-2022-0058543 under 35 U.S.C. § 119, filed on May 12, 2022, in the Korean Intellectual Property Office, the entire contents of which are incorporated herein by reference.

### BACKGROUND

### 1. Technical Field

Embodiments relate to a display device.

### 2. Description of the Related Art

Recently, a light emitting diode display as a self-light emitting display device has attracted attention as a device for displaying an image.

The light emitting diode display has a self-luminance characteristic and may not require a separate light source, unlike a liquid crystal display (LCD) device, and thus may have reduced thickness and weight. Further, the light emitting diode display represents high quality characteristics of low power consumption, high luminance, and a high reaction speed.

In general, the light emitting display device may include a substrate, a plurality of thin film transistors positioned on the substrate, a plurality of insulating layers disposed between wires constituting the thin film transistors, and an organic light emitting element connected to the thin film transistors.

Unintentional capacitances (e.g., parasitic capacitances or coupling capacitances) may occur between a plurality of wires of the display device, which may deteriorate image quality characteristics or increase a luminance deviation according to process dispersion.

The above information disclosed in this Background section is only for enhancement of understanding of the background of the invention, and therefore it may contain information that does not form the prior art that is already known in this country to a person of ordinary skill in the art.

### SUMMARY

Embodiments provide a display device capable of reducing a capacitance between a light emitting control line and a gate electrode of a driving transistor and reducing a luminance deviation caused by process dispersion.

However, embodiments of the disclosure are not limited to those set forth herein. The above and other embodiments will become more apparent to one of ordinary skill in the art to which the disclosure pertains by referencing the detailed description of the disclosure given below.

A display device according to an embodiment includes: a substrate; a semiconductor layer disposed on the substrate; a gate conductive layer disposed on the semiconductor layer; and a first data conductive layer disposed on the gate conductive layer, wherein the gate conductive layer includes a first scan line and a light emitting control line extending along a first direction, and a first gate electrode disposed between the first scan line and the light emitting control line in a plan view, the first data conductive layer includes a first connecting member overlapping the first gate electrode, the first connecting member includes a recessed opening and a hole opening, and a part of the hole opening is disposed between the first gate electrode and the light emitting control line in a plan view.

The recessed opening and the hole opening of the first connecting member may be adjacent to each other in a second direction perpendicular to the first direction.

A width of the hole opening of the first connecting member in the first direction and a width of the recessed opening of the first connecting member in the first direction may be substantially same as each other.

The first data conductive layer may further include a second connecting member, and the second connecting member may be in contact with the first gate electrode in the recessed opening of the first connecting member.

A part of the second connecting member may be in contact with the semiconductor layer, and the second connecting member may electrically connect the first gate electrode and the semiconductor layer.

The first connecting member may include a protrusion protruding in the second direction, and the protrusion of the first connecting member may be in contact with the semiconductor layer.

A second data conductive layer disposed on the first data conductive layer may be further included, and the second data conductive layer may further include a driving voltage line extending along a second direction perpendicular to the first direction.

The driving voltage line may overlap a recessed opening and a hole opening of the first connecting member.

A part of the driving voltage line may be in contact with the first connection member.

The first data conductive layer may further include a first scan auxiliary line extending along the first direction, and the first scan auxiliary line may be electrically connected to the first scan line.

A display device according to another embodiment includes: a substrate; a semiconductor layer disposed on the substrate; a gate conductive layer disposed on the semiconductor layer; and a first data conductive layer disposed on the gate conductive layer, wherein the gate conductive layer includes a first scan line, a light emitting control line, a shielding pattern layer extending along a first direction, and a first gate electrode disposed between the first scan line and the light emitting control line in a plan view, the first data conductive layer includes a first connecting member overlapping the first gate electrode, the first connecting member includes a first recessed opening and a second recessed opening, and the shielding pattern layer is disposed across the second recessed opening in the first direction.

The first recessed opening and the second recessed opening of the first connecting member may be disposed symmetrically to each other.

Edge portions of the shielding pattern layer in the first direction may be in contact with the first connecting member, respectively.

The shielding pattern layer may be disposed between the first gate electrode and the light emitting control line in a plan view.

The first data conductive layer may further include a second connecting member, the second connecting member may be in contact with the first gate electrode at the first recessed opening of the first connecting member, and a part of the second connecting member may be in contact with the semiconductor layer.

The first connecting member may include a protrusion protruding in a second direction perpendicular to the first direction, and the protrusion of the first connecting member may be in contact with the semiconductor layer.

A second data conductive layer disposed on the first data conductive layer may be further included, and the second data conductive layer may include a driving voltage line extending along a second direction perpendicular to the first direction.

The driving voltage line may overlap a first recessed opening and a second recessed opening of the first connecting member.

An entire region of the first recessed opening may overlap the driving voltage line, and a part of the region of the second recessed opening may not overlap the driving voltage line.

A part of the driving voltage line may be in contact with the first connection member.

According to embodiments, there is provided the display device that reduces the capacitance between the light emitting control line and the gate electrode of the driving transistor and reduces a luminance deviation due to process dispersion.

### BRIEF DESCRIPTION OF THE DRAWINGS

FIG. 1 is a schematic diagram of an equivalent circuit of a pixel of a display device according to an embodiment.

FIG. 2 is a schematic layout view of a pixel of a display device according to an embodiment.

FIG. 3 is a schematic cross-sectional view taken along line III-III′ of FIG. 2.

FIG. 4 is a schematic view showing the same region as that of FIG. 2 illustrating a display device according to an embodiment.

FIG. 5 is a schematic cross-sectional view taken along line V-V′ of FIG. 4.

FIG. 6 is a schematic view showing the same region as that of FIG. 2 illustrating a display device according to an embodiment.

FIG. 7 is a schematic cross-sectional view taken along line VII-VII′ of FIG. 6.

FIG. 8 is a schematic view showing the same region as that of FIG. 2 illustrating a display device according to an embodiment.

FIG. 9 is a schematic cross-sectional view taken along line IX-IX′ of FIG. 8.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

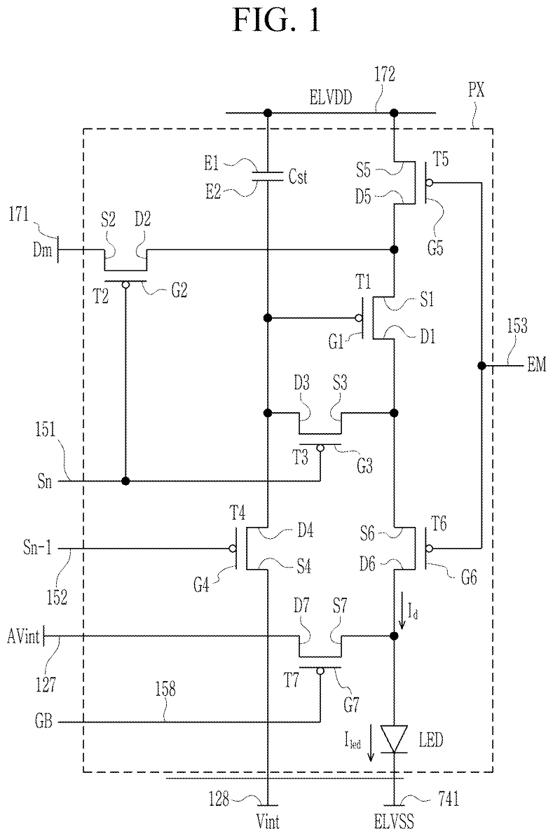

Hereinafter, a display device according to an embodiment is described with reference to accompanying drawings. FIG. 1 is a schematic diagram of an equivalent circuit of a pixel of a display device according to an embodiment. Referring to FIG. 1, a pixel PX of a light emitting display device may include a plurality of transistors T1, T2, T3, T4, T5, T6, and T7, a storage capacitor Cst, and a light-emitting element LED that are connected (e.g., electrically connected) to several signal lines 127, 128, 151, 152, 153, 158, 171, 172, and 741.

A plurality of transistors T1, T2, T3, T4, T5, T6, and T7 may include first to seventh transistors T1, T2, T3, T4, T5, T6, and T7 for the operation of the light-emitting element LED. For example, the first transistor T1 may be a driving transistor, and the second transistor T2 may be a switching transistor connected (e.g., electrically connected) to a first scan line 151. For example, the third to seventh transistors T3, T4, T5, T6, and T7 may be compensation transistors.

A plurality of signal lines 127, 128, 151, 152, 153, 158, 171, 172, and 741 may include a first scan line 151, a second scan line 152, a light emitting control line 153, a bypass control line 158, a data line 171, a driving voltage line 172, a first initialization voltage line 127, a second initialization voltage line 128, and a common voltage line 741. In another example, the first initialization voltage line 127 and the second initialization voltage line 128 may be integral with each other such that the first initialization voltage line 127 and the second initialization voltage line 128 may transmit the same initialization voltage.

The first scan line 151 may be connected (e.g., electrically connected) to a gate driver and may transmit a scan signal Sn to the second transistor T2 and the third transistor T3. The second scan line 152 may be connected (e.g., electrically connected) to the gate driver and may transmit a previous-stage scan signal S(n−1) applied to the pixel PX positioned at the previous stage to the fourth transistor T4. The light emitting control line 153 may be connected (e.g., electrically connected) to the light emitting controller, and may transmit a light emitting control signal (EM) for controlling a light-emitting time of the light-emitting element LED to the fifth transistor T5 and the sixth transistor T6. A bypass control line 158 may transmit a bypass signal GB to the seventh transistor T7.

A data line 171 may be a wire that transmits a data voltage Dm generated by a data driver, and a luminance of the light-emitting element LED may be changed or adjusted according to the data voltage Dm. A driving voltage line 172 may apply a driving voltage ELVDD. The first initialization voltage line 127 may transmit a first initialization voltage AVint that initializes the anode of the light-emitting element LED, and the second initialization voltage line 128 may transmit a second initialization voltage Vint that initializes the driving transistor T1.

A common voltage line 741 may apply a common voltage ELVSS. A constant voltage may be applied to each of the voltages applied to the driving voltage line 172, the first initialization voltage line 127, the second initialization voltage line 128, and the common voltage line 741.

Hereinafter, a plurality of transistors are described.

The driving transistor T1 may be a transistor that adjusts the magnitude of the output current according to the applied data voltage Dm. The output driving current Id may be applied to the light-emitting element LED to adjust the brightness of the light-emitting element LED according to the data voltage Dm. For example, the first electrode S1 of the driving transistor T1 may be disposed to receive the driving voltage ELVDD. The first electrode S1 may be connected (e.g., electrically connected) to the driving voltage line 172 via the fifth transistor T5. For example, the first electrode S1 of the driving transistor T1 may be connected (e.g., electrically connected) to the second electrode D2 of the second transistor T2, so that the data voltage may be applied thereto. The second electrode D1 (e.g., an output electrode) of the driving transistor T1 may be disposed to output the current toward the light-emitting element LED. The second electrode D1 of the driving transistor T1 may be connected (e.g., electrically connected) to the anode of the light-emitting element LED via the sixth transistor T6. For example, the gate electrode G1 may be connected (e.g., electrically connected) to one electrode (e.g., a second storage electrode E2) of the storage capacitor Cst. Therefore, the voltage of the gate electrode G1 may change according to the voltage stored in the storage capacitor Cst, and accordingly, the driving current Id output by the driving transistor T1 may be changed.

The second transistor T2 may be a transistor that receives the data voltage Dm into the pixel PX. The gate electrode G2 may be connected (e.g., electrically connected) to the first scan line 151, and the first electrode S2 may be connected (e.g., electrically connected) to the data line 171. The second electrode D2 of the second transistor T2 may be connected (e.g., electrically connected) to the first electrode S1 of the driving transistor T1. In case that the second transistor T2 is turned on according to the scan signal Sn transmitted through the first scan line 151, the data voltage Dm transmitted through the data line 171 may be transmitted to the first electrode S1 of the driving transistor T1.

The third transistor T3 may be a transistor for transmitting a voltage of the compensation voltage (Dm+Vth) of which the data voltage Dm is changed through the driving transistor T1 to the second storage electrode E2 of the storage capacitor Cst. The gate electrode G3 may be connected (e.g., electrically connected) to the first scan line 151, and the first electrode S3 may be connected (e.g., electrically connected) to the second electrode D1 of the driving transistor T1. The second electrode D3 of the third transistor T3 may be connected (e.g., electrically connected) to the second storage electrode E2 of the storage capacitor Cst and the gate electrode G1 of the driving transistor T1. The third transistor T3 may be turned on according to the scan signal Sn transmitted through the first scan line 151 so that the gate electrode G1 and the second electrode D1 of the driving transistor T1 may be connected, and the second electrode D1 of the driving transistor T1 and the second storage electrode E2 of the storage capacitor Cst may be connected.

The fourth transistor T4 may function to initialize the gate electrode G1 of the driving transistor T1 and the second storage electrode E2 of the storage capacitor Cst. The gate electrode G4 may be connected (e.g., electrically connected) to the second scan line 152, and the first electrode S4 may be connected (e.g., electrically connected) to the second initialization voltage line 128. The second electrode D4 of the fourth transistor T4 may be connected (e.g., electrically connected) to the second storage electrode E2 of the storage capacitor Cst and the gate electrode G1 of the driving transistor T1 via the second electrode D3 of the third transistor T3. The fourth transistor T4 may transfer the initialization voltage to the gate electrode G1 of the driving transistor T1 and the second storage electrode E2 of the storage capacitor Cst according to the previous scan signal S(n−1) received through the previous scan line 152. Accordingly, the gate voltage of the gate electrode G1 of the driving transistor T1 and the storage capacitor Cst may be initialized. The second initialization voltage Vint may have a low voltage value and may be a voltage capable of turning on the driving transistor T1.

The fifth transistor T5 may function to transmit the driving voltage to the driving transistor T1. The gate electrode G5 may be connected (e.g., electrically connected) to the light emitting control line 153, and the first electrode S5 may be connected (e.g., electrically connected) to the driving voltage line 172. The second electrode D5 of the fifth transistor T5 may be connected (e.g., electrically connected) to the first electrode S1 of the driving transistor T1.

The sixth transistor T6 may function to transmit the driving current Id output from the driving transistor T1 to the light-emitting element LED. The gate electrode G6 may be connected (e.g., electrically connected) to the light emitting control line 153, and the first electrode S6 may be connected (e.g., electrically connected) to the second electrode D1 of the driving transistor T1. The second electrode D6 of the sixth transistor T6 may be connected (e.g., electrically connected) to the anode of the light-emitting element LED.

The fifth transistor T5 and the sixth transistor T6 may be simultaneously turned on according to the light emission control signal transmitted through the light emitting control line 153, and in case that the driving voltage ELVDD is applied to the first electrode S1 of the driving transistor T1 through the fifth transistor T5, the driving transistor T1 may output the driving current Id according to the voltage (e.g., the voltage of the second storage electrode E2 of the storage capacitor Cst) of the gate electrode G1 of the driving transistor T1. The output driving current Id may be transmitted to the light emitting element LED through the sixth transistor T6. As the current I_{led} flows through the light emitting element LED, the light emitting diode (LED) may emit light.

The seventh transistor T7 may function to initialize the anode of the light-emitting element LED. The gate electrode G7 may be connected (e.g., electrically connected) to the bypass control line 154, the first electrode S7 may be connected (e.g., electrically connected) to the anode of the light emitting element LED, and the second electrode D7 may be connected (e.g., electrically connected) to the first initialization voltage line 127. The bypass control line 154 may be connected (e.g., electrically connected) to the second scan line 152, and the bypass signal may be applied with the same timing signal as the previous scan signal S(n−1). The bypass control line 158 may not be connected (e.g., electrically connected) to the second scan line 152 and may transmit a signal separate from the previous scan signal S(n−1). In case that the seventh transistor T7 is turned on according to the bypass signal GB, the first initialization voltage AVint may be applied to the anode of the light emitting element LED to be initialized.

The first storage electrode E1 of the storage capacitor Cst may be connected (e.g., electrically connected) to the driving voltage line 172, and the second storage electrode E2 may be connected (e.g., electrically connected) to the gate electrode G1 of the driving transistor T1, the second electrode D3 of the third transistor T3, and the second electrode D4 of the fourth transistor T4. Thus, the second storage electrode E2 may determine the voltage of the gate electrode G1 of the driving transistor T1, and the data voltage Dm may be applied through the second electrode D3 of the third transistor T3, or the second initialization voltage Vint may be applied through the second electrode D4 of the fourth transistor T4.

For example, the anode of the light emitting element LED may be connected (e.g., electrically connected) to the second electrode D6 of the sixth transistor T6 and the first electrode S7 of the seventh transistor T7, and the cathode may be connected (e.g., electrically connected) to the common voltage line 741 that transmits the common voltage ELVSS.

Referring to FIG. 1, one pixel may include seven transistors T1 to T7 and one storage capacitor Cst, but embodiments are not limited thereto, and the number of transistors, the number of capacitors, and their connection relationship may be variously changed.

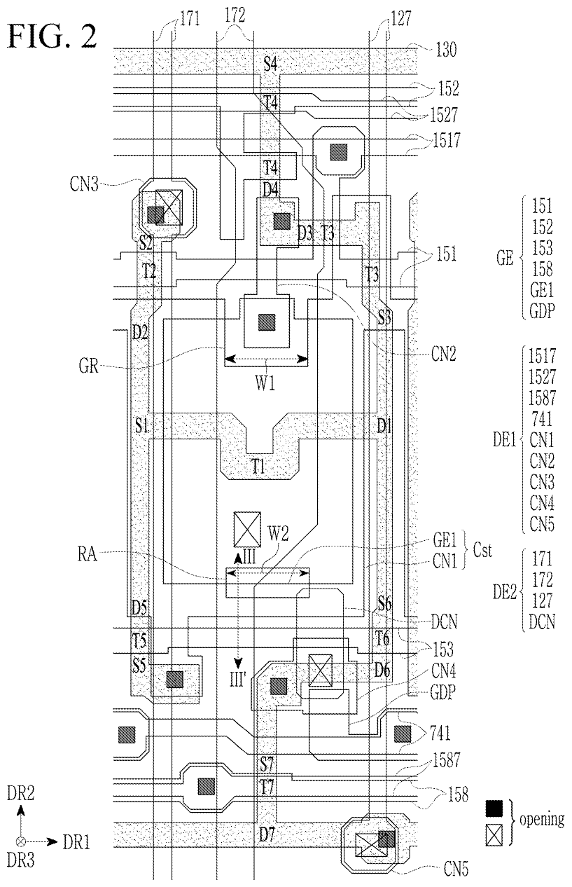

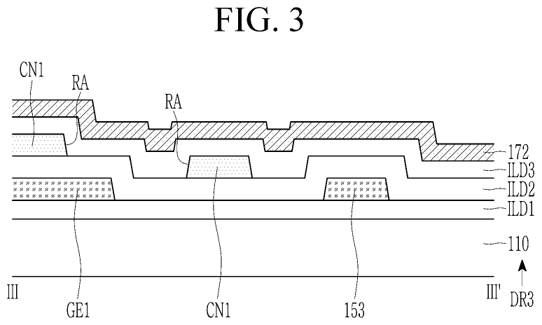

FIG. 2 is a schematic layout view of a pixel of a display device according to an embodiment. FIG. 3 is a schematic cross-sectional view taken along line III-III′ of FIG. 2.

Referring to FIG. 1 and FIG. 2, a light emitting display device according to an embodiment may include a first scan line 151 extending along a first direction DR1 and transmitting a scan signal Sn, a second scan line 152 transmitting a previous scan signal S(n−1), a light emitting control line 153 transmitting a light emitting control signal EM, and a bypass control line 158 transmitting a bypass signal GB.

For example, the light emitting display device may include a data line 171 extending in a second direction DR2 intersecting the first direction DR1 and transmitting the data voltage Dm, a driving voltage line 172 transmitting the driving voltage ELVDD, and a first initialization voltage line 127 transmitting the first initialization voltage AVint.

The light emitting display device may include the driving transistor T1, the second transistor T2, the third transistor T3, the fourth transistor T4, the fifth transistor T5, the sixth transistor T6, the seventh transistor T7, the storage capacitor Cst, and the light-emitting element LED.

Each channel of the driving transistor T1, the second transistor T2, the third transistor T3, the fourth transistor T4, the fifth transistor T5, the sixth transistor T6, and the seventh transistor T7 may be disposed in the semiconductor layer 130 extending to be elongated. At least part of the first electrode and the second electrode of the plurality of transistors T1, T2, T3, T4, T5, T6, and T7 may be disposed in the semiconductor layer 130. The semiconductor layer 130 (e.g., a part in which the shade is added in FIG. 2) may be formed to be bent in various shapes. The semiconductor layer 130 may include a polycrystalline semiconductor such as polysilicon, or an oxide semiconductor.

The semiconductor layer 130 may include a channel doped with an n-type impurity (or dopant) or a p-type impurity (or dopant), and a first doping region and a second doping region. For example, the first doping region and the second doping region may have a doping concentration higher than that of the impurity doped with the channel. The first doping region and the second doping region may be the first electrode and the second electrode of the plurality of transistors T1, T2, T3, T4, T5, T6, and T7, respectively. One of the first doping region and the second doping region may be the source region, and another one may be the drain region. In the semiconductor layer 130, a region between the first electrode and the second electrode of different transistors from each other may be doped such that two transistors may be connected (e.g., electrically connected) to each other.

Each channel of the plurality of transistors T1, T2, T3, T4, T5, T6, and T7 may overlap the gate electrode of each transistor T1, T2, T3, T4, T5, T6, and T7 and may be disposed between the first electrode and the second electrode of each transistor T1, T2, T3, T4, T5, T6, and T7. A plurality of transistors T1, T2, T3, T4, T5, T6, and T7 may have substantially the same stacked structure. Hereinafter, the driving transistor T1 may be described in detail, and the remaining transistors T2, T3, T4, T5, T6, and T7 are described.

The driving transistor T1 may include a channel, a first gate electrode GE1, a first electrode S1, and a second electrode D1. The channel of the driving transistor T1 may be between the first electrode S1 and the second electrode D1 and may overlap the first gate electrode GE1 in a plan view. As explained below, a first connecting member CN1, which is a data conductive layer, may be positioned by overlapping the first gate electrode GE1. The first gate electrode GE1 and the first connecting member CN1 may be overlapped via the second insulating layer ILD2 interposed therebetween to form a storage capacitor Cst. The first connecting member CN1 may form the first storage electrode (e.g., E1 in FIG. 1) of the storage capacitor Cst, and the first gate electrode GE1 may form the second storage electrode (e.g., E2 in FIG. 1).

The gate electrode of the second transistor T2 may be a part of the first scan line 151. The data line 171 may be connected (e.g., electrically connected) to the first electrode S2 of the second transistor T2 through an opening. The first electrode S2 and the second electrode D2 may be positioned on the semiconductor layer 130.

The third transistor T3 may be formed of two transistors adjacent to each other. In FIG. 2, a character reference T3 is shown on the left and lower sides with respect to the part where the semiconductor layer 130 is bent. These two parts each may perform a role of the third transistor T3, and may have a structure in which the first electrode S3 of one third transistor T3 is connected (e.g., electrically connected) to the second electrode D3 of another third transistor T3. The gate electrode of two transistors T3 may be a part of the first scan line 151 or a part protruded upward from the first scan line 151. Such a structure may be referred to as a dual gate structure, and may function to block a leakage current from flowing. The first electrode S3 of the third transistor T3 may be connected (e.g., electrically connected) to the first electrode S6 of the sixth transistor T6 and the second electrode D1 of the driving transistor T1. The second electrode D3 of the third transistor T3 may be connected (e.g., electrically connected) to the second connecting member CN2 through an opening.

The fourth transistor T4 may be formed of two fourth transistors T4, and two fourth transistors T4 may be formed at a portion where the second scan line 152 and the semiconductor layer 130 meet. The gate electrode of the fourth transistor T4 may be a part of the second scan line 152. The first electrode S4 of one fourth transistor T4 may be connected (e.g., electrically connected) to the second electrode D4 of another fourth transistor T4. Such a structure may be referred to as a dual gate structure, and may function to block a leakage current. The second electrode D4 of the fourth transistor T4 may be connected (e.g., electrically connected) to the second connecting member CN2 through an opening. For example, the fourth transistor may be connected (e.g., electrically connected) to a second initialization voltage line to receive a second initialization voltage.

Accordingly, by using the dual gate structure as the third transistor T3 and the fourth transistor T4, the leakage current may be effectively prevented by blocking an electron moving path of the channel in the off state.

The gate electrode of the fifth transistor T5 may be a part of the light emitting control line 153. The first connecting member CN1 may be connected (e.g., electrically connected) to the first electrode S5 of the fifth transistor T5 through an opening, and the first connecting member CN1 may be connected (e.g., electrically connected) to the driving voltage line 172 through an opening. The second electrode D5 of the fifth transistor T5 may be connected (e.g., electrically connected) to the first electrode S1 of the driving transistor T1 through the semiconductor layer 130.

The gate electrode of the sixth transistor T6 may be a part of the light emitting control line 153. The fourth connecting member CN4 may be connected (e.g., electrically connected) to the second electrode D6 of the sixth transistor T6 through an opening, and the first electrode S6 may be connected (e.g., electrically connected) to the second electrode D1 of the driving transistor through the semiconductor layer 130.

The gate electrode of the seventh transistor T7 may be a part of the bypass control line 158. The first electrode S7 of the seventh transistor T7 may be connected (e.g., electrically connected) to the second electrode D6 of the sixth transistor T6.

The storage capacitor Cst may include a first storage electrode E1 and a second storage electrode E2 that overlap via the second insulating layer ILD2 interposed therebetween. The second storage electrode E2 may be the first gate electrode GE1 of the driving transistor T1, and the first storage electrode E1 may be the first connecting member CN1. For example, the second insulating layer ILD2 may be formed of a dielectric material, and the capacitance may be determined by the charge accumulated in the storage capacitor Cst and the voltage between the first and second storage electrodes E1 and E2.

The driving voltage line 172 may be connected (e.g., electrically connected) to the first connecting member CN1 through an opening. Therefore, the storage capacitor Cst stores a charge corresponding to the difference between the driving voltage ELVDD transmitted to the first connecting member CN1 through the driving voltage line 172 and the gate voltage of the first gate electrode GE1.

Hereinafter, the structure on the cross-section of the light emitting display device according to an embodiment is described according to the stacking sequence with reference to FIG. 2 in addition to FIG. 3.

Referring to FIG. 2 and FIG. 3, the semiconductor layer 130 may be positioned on the substrate 110. Each channel of the driving transistor T1, the second transistor T2, the third transistor T3, the fourth transistor T4, the fifth transistor T5, the sixth transistor T6, and the seventh transistor T7 may be positioned in the semiconductor layer 130 extending long. For example, at least some of the first and second electrodes of a plurality of transistors T1, T2, T3, T4, T5, T6, and T7 may be positioned in the semiconductor layer 130.

The semiconductor layer 130 may include a channel doped with an n-type impurity (or dopant) or a p-type impurity (or dopant), and a first doping region and a second doping region. For example, the first doping region and the second doping region may have a doping concentration higher than that of the impurity doped with the channel. The first doping region and the second doping region correspond to the first electrode and the second electrode of the plurality of transistors T1, T2, T3, T4, T5, T6, and T7, respectively.

The first insulating layer ILD1 may be positioned on the semiconductor layer 130. The first insulating layer ILD1 may include a silicon oxide (SiOₓ), a silicon nitride (SiNₓ), and a silicon oxynitride (SiOₓN_{y}), and may have a single-layered structure or a multi-layered structure.

A gate conductive layer GE may be positioned on the first insulating layer ILD1. The gate conductive layer GE may include molybdenum (Mo), aluminum (Al), copper (Cu), silver (Ag), chromium (Cr), tantalum (Ta), titanium (Ti), etc., and have a single-layered structure or a multi-layered structure.

The gate conductive layer GE may include a first scan line 151, a second scan line 152, a light emitting control line 153, a bypass control line 158, and a first gate electrode GE1, and a dummy pattern layer GDP positioned along the first direction DR1. The first scan line 151 and the second scan line 152 may include a portion protruded in the second direction DR2.

The first gate electrode GE1 may be positioned between the first scan line 151 and the light emitting control line 153 in a plan view. The first gate electrode GE1 may overlap the driving transistor T1 to form the gate electrode of the driving transistor T1.

For example, the dummy pattern layer GDP may be positioned between the light emitting control line 153 and the bypass control line 158 in a plan view. The dummy pattern layer GDP may overlap the common voltage line 741 and may be in contact with the common voltage line 741 through an opening.

A second insulating layer ILD2 may be positioned on the gate conductive layer GE. The second insulating layer ILD2 may include a silicon oxide (SiOₓ), a silicon nitride (SiNₓ), and a silicon oxynitride (SiOₓN_{y}), and may have a single-layered structure or a multi-layered structure.

A first data conductive layer DE1 may be positioned on the second insulating layer ILD2. The first data conductive layer DE1 may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), and/or copper (Cu), and may be a single-layered structure or a multi-layered structure.

The first data conductive layer DE1 may include a first scan auxiliary line 1517, a second scan auxiliary line 1527, a bypass auxiliary line 1587, and a common voltage line 741 positioned along the second direction DR2.

The first scan auxiliary line 1517 may be connected (e.g., electrically connected) to the first scan line 151 through an opening. For example, the second scan auxiliary line 1527 may be connected (e.g., electrically connected) to the second scan line 152 through an opening. The bypass auxiliary line 1587 may be connected (e.g., electrically connected) to the bypass control line 158 through an opening. Since each of the first scan line 151, the second scan line 152, and the bypass control line 158 may have a two-layered structure connected (e.g., electrically connected) to the data conductive layer, respectively, and the voltage may be transferred to the double layer, a wire resistance may be reduced.

For example, the first data conductive layer DE1 may include a plurality of connecting members CN1, CN2, CN3, CN4, and CN5. The first connecting member CN1 may overlap the first gate electrode GE1 and may form the storage capacitor Cst. For example, as described above, the first connecting member CN1 may form the storage capacitor Cst together with the first gate electrode GE1.

The first connecting member CN1 may include a protrusion protruded in the second direction DR2. For example, the semiconductor layer 130 and the first connecting member CN1 may be in contact through the opening overlapping the protrusion. Referring to FIG. 2, the fifth transistor T5 of the semiconductor layer 130 and the first connecting member CN1 may be connected (e.g., electrically connected) to each other.

Referring to FIG. 2, a part of the first connecting member CN1 does not overlap the first gate electrode GE1. For example, as shown in FIG. 2, the first connecting member CN1 may include a recessed part (or a recessed opening) GR and a ring area (or a hole opening) RA. The recessed part (or the recessed opening) GR and the ring area (or the hole opening) RA may be parts where the first connecting member CN1 is removed so that the first connecting member CN1 and the first gate electrode GE1 do not overlap. In the recessed part (or the recessed opening) GR, the second connecting member CN2 and the first gate electrode GE1 may be in contact through an opening. The second connecting member CN2 may be in contact with the semiconductor layer 130 through another opening. For example, the second connecting member CN2 may connect the first gate electrode GE1 and the semiconductor layer 130.

As shown in FIG. 2, the recessed part (or the recessed opening) GR and the ring area (or the hole opening) RA may be positioned symmetrically. For example, the recessed part (or the recessed opening) GR and the ring area (or the hole opening) RA may be positioned on the same line in the second direction DR2. In FIG. 2, a width W1 of the recessed part (or the recessed opening) GR in the first direction DR1 and a width W2 of the ring area (or the hole opening) RA in the first direction DR1 may be the same as each other. In the descriptions, the expression “the same” may mean up to a case where the difference is less than about 5%. As above-described, the recessed part (or the recessed opening) GR and the ring area (or the hole opening) RA may be positioned symmetrically, so the change rate of the capacitance of the storage capacitor may be reduced or minimized in case that the positions of the first gate electrode GE1 and the first connecting member CN1 are misaligned during the process.

The ring area (or the hole opening) RA may be a region from which the first connecting member CN1 is removed, and the ring area (or the hole opening) RA may overlap the edge portion of the first gate electrode GE1. Referring to the cross-section of FIG. 3, as above-described, the first connecting member CN1 may include the ring area (or the hole opening) RA, and the first connecting member CN1 may be positioned between the first gate electrode GE1 and the light emitting control line 153. For example, as illustrated in FIG. 2, a part of the first connecting member CN1 may be positioned between the first gate electrode GE1 and the light emitting control line 153 in a plan view. Although this is separately described below, the capacitance formed between the first gate electrode GE1 and the light emitting control line 153 may be reduced. For example, the first connecting member CN1 positioned between the first gate electrode GE1 and the light emitting control line 153 in a plan view may function as a shielding electrode, thereby preventing an unintentional capacitance (e.g., a parasitic capacitance or a coupling capacitance) from occurring between the first gate electrode GE1 and the light emitting control line 153, and detailed effects are described below.

The third connecting member CN3 may be connected (e.g., electrically connected) to the second transistor T2 of the semiconductor layer 130 through an opening. The fourth connecting member CN4 may be connected (e.g., electrically connected) to the sixth transistor T6 of the semiconductor layer 130 through an opening. The fifth connecting member CN5 may be connected (e.g., electrically connected) to the seventh transistor T7 of the semiconductor layer 130 through an opening.

A third insulating layer ILD3 may be positioned on the first data conductive layer DE1. The third insulating layer ILD3 may include a silicon oxide (SiOₓ), a silicon nitride (SiNₓ), and a silicon oxynitride (SiOₓN_{y}), and may have a single-layered structure or a multi-layered structure including these.

A second data conductive layer DE2 may be positioned on the third insulating layer ILD3. The second data conductive layer DE2 may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), and/or copper (Cu), and/or may be a single-layered structure or a multi-layered structure. The second data conductive layer DE2 may include a data line 171, a driving voltage line 172, a first initialization voltage line 127, and an element connecting member DCN positioned along the second direction DR2.

The data line 171 may be in contact with the third connecting member CN3 through an opening positioned on the third insulating layer ILD3. The third connecting member CN3 may be connected (e.g., electrically connected) to the second transistor T2 through the opening positioned in the second insulating layer ILD2, so the data voltage of the data line 171 may be transferred to the second transistor T2.

The driving voltage line 172 may be in contact with the first connecting member CN1 through an opening positioned on the third insulating layer ILD3. The first connecting member CN1 may be connected (e.g., electrically connected) to the fifth transistor T5 through the opening positioned in the second insulating layer ILD2, and thus the driving voltage may be transmitted to the fifth transistor T5. Referring to FIG. 2 and FIG. 3, the driving voltage line 172 may overlap the recessed part (or the recessed opening) GR. For example, the driving voltage line 172 may overlap a part of the ring area (or the hole opening) RA.

The first initialization voltage line 127 may be in contact with the fifth connecting member CN5 through an opening positioned on the third insulating layer ILD3. The fifth connecting member CN5 may be connected (e.g., electrically connected) to the seventh transistor T7 through an opening positioned on the second insulating layer ILD2, so that an initialization voltage may be transmitted to the seventh transistor T7.

The element connecting member DCN may be in contact with the fourth connecting member CN4 through the opening positioned on the third insulating layer ILD3. The fourth connecting member CN5 may be connected (e.g., electrically connected) to the sixth transistor T6 through an opening positioned in the second insulating layer ILD2.

For example, the element connecting member DCN may be connected (e.g., electrically connected) to the light-emitting device. Accordingly, the driving current transferred to the sixth transistor T6 may be transferred to the light-emitting element.

Referring to FIG. 2 and FIG. 3, in the display device according to an embodiment, the first connecting member CN1 may be positioned between the first gate electrode GE1 and the light emitting control line 153 in a plan view. By this first connecting member CN1, the capacitance between the first gate electrode GE1 and the light emitting control line 153 may be reduced as compared to a conventional or typical structure.

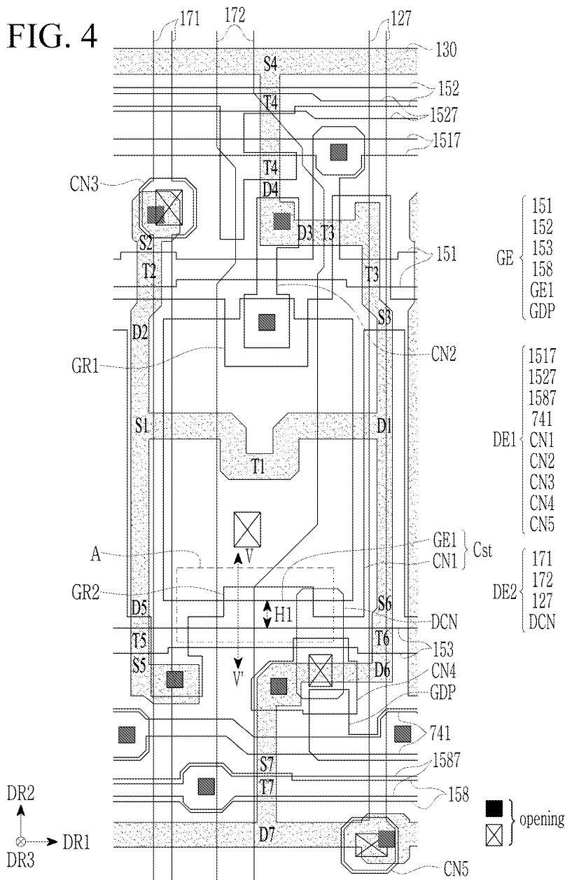

FIG. 4 is a schematic view showing the same region as that of FIG. 2 illustrating a display device according to an embodiment. The embodiment of FIG. 4 is substantially the same as the embodiment FIG. 1 except that the first connecting member CN1 does not include the ring area (or the hole opening) RA. The description of the same constituent elements is omitted for descriptive convenience. In the embodiment of FIG. 4, the different part from FIG. 1 is indicated by a region A. The embodiment of FIG. 4 may include a first recessed part (or a first recessed opening) GR1 and a second recessed part (or a second recessed opening) GR2 without including the ring area (or the hole opening) RA.

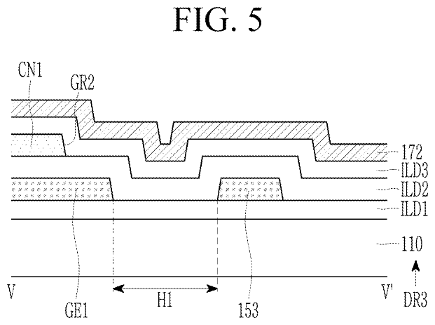

FIG. 5 is a schematic cross-sectional view taken along line V-V′ of FIG. 4. Referring to FIG. 5, the first connecting member CN1 may not be positioned between the first gate electrode GE1 and the light emitting control line 153.

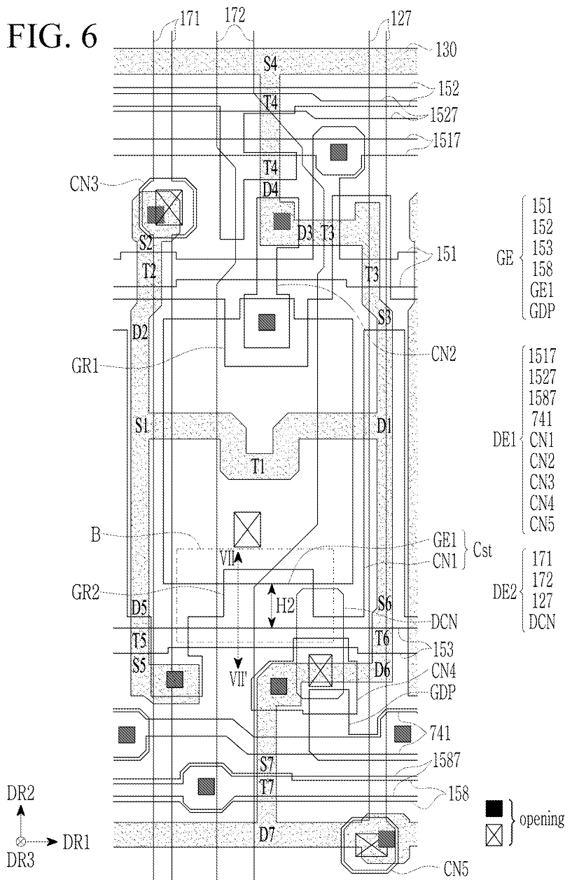

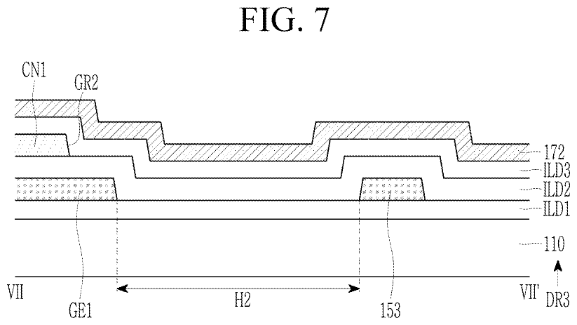

FIG. 6 is a schematic view showing the same region as that of FIG. 2 illustrating a display device according to an embodiment. The embodiment of FIG. 6 is substantially the same as the embodiment of FIG. 1 except that the first connecting member CN1 does not includes the ring area (or the hole opening) RA. The description for the same constituent elements is omitted for descriptive convenience. In the embodiment of FIG. 6, a portion that is different from FIG. 1 is indicated by a region B. The embodiment of FIG. 6 may include the first recessed part (or the first recessed opening) GR1 and the second recessed part (or the second recessed opening) GR2 without including the ring area (or the hole opening) RA. Comparing FIG. 4 with FIG. 6, in the embodiment of FIG. 6, a distance H2 between the first gate electrode GE1 and the light emitting control line 153 is wider than a distance H1 of FIG. 4. FIG. 7 is a schematic cross-sectional view taken along line VII-VII′ of FIG. 6. Referring to FIG. 7, the first connecting member CN1 may not be positioned between the first gate electrode GE1 and the light emitting control line 153. Comparing FIG. 5 with FIG. 7, the distance H2 between the first gate electrode GE1 and the light emitting control line 153 in FIG. 7 may be longer than the distance H1 between the first gate electrode GE1 and the light emitting control line 153 in FIG. 5.

Like the embodiment of FIG. 4 and FIG. 6, the first connecting member CN1 may not be positioned between the first gate electrode GE1 and the light emitting control line 153. For example, the capacitance may be formed between the light emitting control line 153 and the first gate electrode GE1.

For the embodiments of FIG. 2, FIG. 4, and FIG. 6, the capacitance formed between the first gate electrode GE1 and the light emitting control line 153 and a luminance deviation are respectively measured and results thereof are described in Table 1 below. For example, each of the capacitance and the luminance deviation may be measured for an aligned state (Original), a state (SD CD−0.1, SD CD+0.1) in which a process deviation of the first data conductive layer DE1 occurs, and a state (GAT1 CD−0.1, GAT1 CD+0.1) in which a process deviation of the gate conductive layer GE occurs. For example, an average value (a luminance deviation Avg by CD) of a luminance deviation due to the process deviation may be measured.

TABLE 1

| | Embodiment 1 (FIG. 2) | | Embodiment 2 (FIG. 4) | | Embodiment 3 (FIG. 6) | |
|---|---|---|---|---|---|---|
| | EM-GATE | Luminance | EM-GATE | Luminance | EM-GATE | Luminance |
| | cap. | deviation | cap. | deviation | cap. | deviation |
| Original | 2.08E−16 | — | 4.73E−16 | — | 2.51E−16 | — |
| SD CD −0.1 | 2.15E−16 | +13.8% | 4.89E−16 | +16.1% | 2.57E−16 | +15.4% |
| SD CD +0.1 | 2.03E−16 | −6.7% | 4.54E−16 | −27.5% | 2.47E−16 | −10.5% |
| GAT1 CD −0.1 | 1.72E−16 | −1.1% | 3.81E−16 | −33.7% | 2.10E−16 | −1.6% |
| GAT1 CD +0.1 | 2.30E−16 | +0.5% | 5.18E−16 | +3.8% | 2.87E−16 | +8.4% |
| Luminance | 5.6% | | 20.3% | | 9.0% | |
| deviation Avg. | | | | | | |
| by CD. | | | | | | |

Referring to Table 1, the capacitance of Embodiment 1 in which the first connecting member CN1 is positioned between the first gate electrode GE1 and the light emitting control line 153 (e.g., in a plan view) is lower than the capacitances of Embodiment 2 and Embodiment 3 in which the first connecting member CN1 includes the second recessed part (or the second recessed opening) GR2. In Embodiment 1, the first connecting member CN1 may function as a shielding electrode with being positioned between the first gate electrode GE1 and the light emitting control line 153. The luminance deviation according to the process deviation may be lower in Embodiment 1 in which the first connecting member CN1 is positioned between the first gate electrode GE1 and the light emitting control line 153 (e.g., in a plan view) than Embodiment 2 and Embodiment 3 in which the first connecting member CN1 includes the second recessed part (or the second recessed opening) GR2.

In case that the first connecting member CN1 is positioned between the first gate electrode GE1 and the light emitting control line 153 (e.g., in a plan view), the magnitude of the capacitance formed between the light emitting control line 153 and the first gate electrode GE1 may be reduced. For example, the luminance deviation due to process dispersion during the manufacturing process may be significantly reduced or minimized.

FIG. 2 shows the embodiment in which the first connecting member CN1 of the first data conductive layer DE1 is positioned between the first gate electrode GE1 and the light emitting control line 153 (e.g., in a plan view), however according to an embodiment, the first gate electrode GE1 and the light emitting control line 153 may be shielded by the gate conductive layer GE.

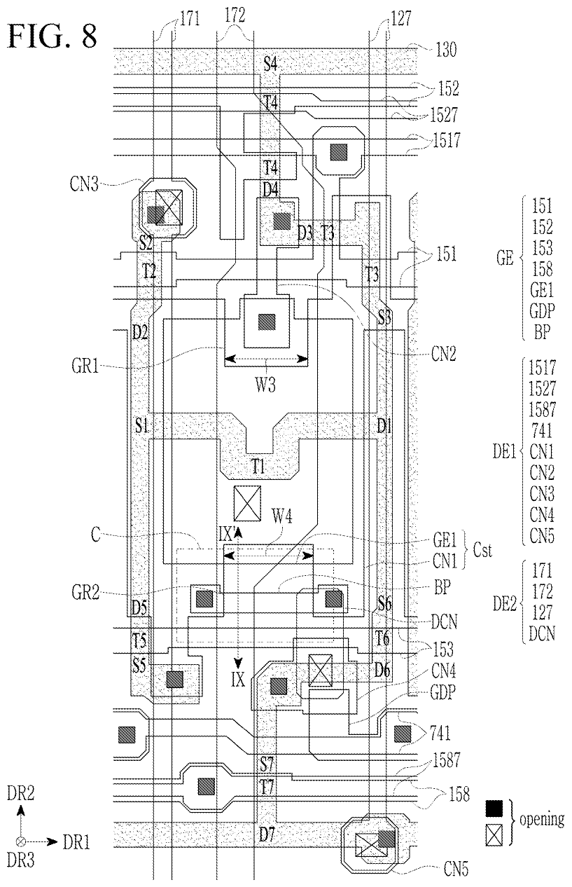

FIG. 8 is a schematic view showing the same region as that of FIG. 2 illustrating a display device according to an embodiment. Referring to FIG. 8, the display device may be substantially the same as that of FIG. 2 except that the first connecting member CN1 does not include the ring area (or the hole opening) RA, but instead includes a shielding pattern layer BP. For example, the shielding pattern layer BP and the gate conductive layer GE may be positioned on the same layer (e.g., the first insulating layer ILD1). The detailed description of the same constituent elements is omitted for descriptive convenience. In the embodiment of FIG. 8, the part different from FIG. 2 is marked by a region C.

Referring to FIG. 8, the first connecting member CN1 may include a first recessed part (or the first recessed opening) GR1 and a second recessed part (or the second recessed opening) GR2 respectively positioned in the second direction DR2. The second recessed part (or the second recessed opening) GR2 may be connected (e.g., electrically connected) to a shielding pattern layer BP. For example, the shielding pattern layer BP and the second recessed part (or the second recessed opening) GR2 may be in contact through an opening. Accordingly, in case that the ring area (or the hole opening) RA of FIG. 2 is formed of the first connecting member CN1, in the case of FIG. 8, the first connecting member CN1 and the shielding pattern layer BP may be connected (e.g., electrically connected), thereby forming the ring shape.

Referring to FIG. 8, the first recessed part (or the first recessed opening) GR1 and the second recessed part (or the second recessed opening) GR2 may be positioned symmetrical to each other. For example, the first recessed part (or the first recessed opening) GR1 and the second recessed part (or the second recessed opening) GR2 may be positioned on the same line in the second direction DR2. For example, the width W3 of the first recessed part (or the first recessed opening) GR1 in the first direction DR1 and the width W4 of the second recessed part (or the second recessed opening) GR2 in the first direction DR1 may be the same as each other. In the descriptions, the expression “the same” may mean up to the case where the difference is less than about 5%. As the first recessed part (or the first recessed opening) GR1 and the second recessed part (or the second recessed opening) GR2 are positioned symmetrically, in case that the positions of the first gate electrode GE1 and the first connecting member CN1 are misaligned during the process, the change rate in the capacitance of the storage capacitor may be reduced.

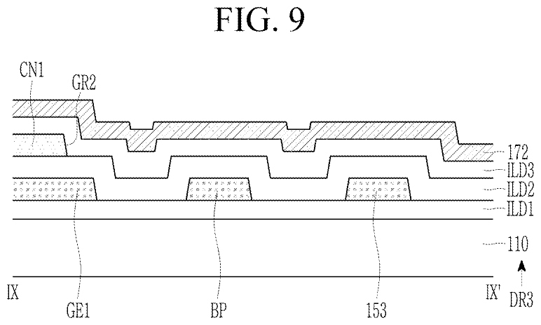

FIG. 9 is a schematic cross-sectional view taken along line IX-IX′ of FIG. 8. Referring to FIG. 9, a shielding pattern layer BP may be positioned between a light emitting control line 153 and a first gate electrode GE1. Accordingly, the magnitude of the capacitance formed between the light emitting control line 153 and the first gate electrode GE1 may be reduced.

Referring to FIG. 8 and FIG. 9, the driving voltage line 172 of the second data conductive layer DE2 may overlap the first recessed part (or the first recessed opening) GR1. For example, the driving voltage line 172 may overlap a part of the second recessed part (or the second recessed opening) GR2.

Table 2 below shows results obtained by measuring the capacitance and the luminance deviation formed between the first gate electrode GE1 and the light emitting control line 153, respectively, for the embodiments of FIG. 4, FIG. 6, and FIG. 8. For example, each capacitance and luminance deviation was measured for an alignment state (Original), a state (SD CD−0.1, SD CD+0.1) in which the process deviation of the first data conductive layer DE1 occurs, and a state (GAT1 CD−0.1, GAT1 CD+0.1) in which the process deviation of the gate conductive layer GE occurs. For example, the average value of the luminance deviation due to the process deviation was measured.

TABLE 2

| | Embodiment 4 (FIG. 8) | | Embodiment 2 (FIG. 4) | | Embodiment 3 (FIG. 6) | |
|---|---|---|---|---|---|---|
| | EM-GATE | Luminance | EM-GATE | Luminance | EM-GATE | Luminance |
| | cap. | deviation | cap. | deviation | cap. | deviation |
| Original | 1.28E−16 | — | 4.73E−16 | — | 2.51E−16 | — |
| SD CD −0.1 | 1.30E−16 | +13.0% | 4.89E−16 | +16.1% | 2.57E−16 | +15.4% |
| SD CD +0.1 | 1.25E−16 | −6.1% | 4.54E−16 | −27.5% | 2.47E−16 | −10.5% |
| GAT1 CD −0.1 | 1.10E−16 | −13.0% | 3.81E−16 | −33.7% | 2.10E−16 | −1.6% |
| GAT1 CD +0.1 | 1.41E−16 | +0.6% | 5.18E−16 | +3.8% | 2.87E−16 | +8.4% |
| Luminance | 8.2% | | 20.3% | | 9.0% | |
| deviation Avg. | | | | | | |
| by CD | | | | | | |

Referring to Table 2, the capacitance of Embodiment 4 in which the shielding pattern layer BP is positioned between the first gate electrode GE1 and the light emitting control line 153 is lower than that of Embodiment 2 and Embodiment 3 without the shielding pattern layer BP. In Embodiment 4, the shielding pattern layer BP may reduce the capacitance between the first gate electrode GE1 and the light emitting control line 153 with being positioned between the first gate electrode GE1 and the light emitting control line 153.

For example, the luminance deviation according to the process deviation appears lower in Embodiment 4 in which the shielding pattern layer BP is positioned between the first gate electrode GE1 and the light emitting control line 153 than Embodiment 2 and Embodiment 3 in which the shielding pattern layer BP is not positioned.

For example, as above-described, in the display device according to an embodiment, in case that the first connecting member CN1 of the first data conductive layer DE1 or the shielding pattern layer BP of the gate conductive layer GE is positioned between the first gate electrode GE1 and the light emitting control line 153 that are adjacent, the capacitance between the first gate electrode GE1 and the light emitting control line 153 may be reduced. For example, the luminance deviation caused by the process dispersion during the manufacturing process may be significantly reduced.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate;
a semiconductor layer disposed on the substrate;
a gate conductive layer disposed on the semiconductor layer; and
a first data conductive layer disposed on the gate conductive layer, wherein the gate conductive layer includes:
a first scan line and a light emitting control line extending along a first direction, and
a first gate electrode disposed between the first scan line and the light emitting control line in a plan view,
the first data conductive layer includes a first connecting member overlapping the first gate electrode,
the first connecting member includes a recessed opening and a hole opening, and
a part of the hole opening is disposed between the first gate electrode and the light emitting control line in a plan view.

2. The display device of claim 1, wherein the recessed opening and the hole opening of the first connecting member are adjacent to each other in a second direction perpendicular to the first direction.

3. The display device of claim 1, wherein a width of the hole opening of the first connecting member in the first direction and a width of the recessed opening of the first connecting member in the first direction are substantially same as each other.

4. The display device of claim 1, wherein
the first data conductive layer further includes a second connecting member, and
the second connecting member is in contact with the first gate electrode in the recessed opening of the first connecting member.

5. The display device of claim 4, wherein
a part of the second connecting member is in contact with the semiconductor layer, and
the second connecting member electrically connects the first gate electrode and the semiconductor layer.

6. The display device of claim 2, wherein
the first connecting member includes a protrusion protruding in the second direction, and
the protrusion of the first connecting member is in contact with the semiconductor layer.

7. The display device of claim 1, further comprising
a second data conductive layer disposed on the first data conductive layer, and
the second data conductive layer further includes a driving voltage line extending along a second direction perpendicular to the first direction.

8. The display device of claim 7, wherein the driving voltage line overlaps a recessed opening and a hole opening of the first connecting member.

9. The display device of claim 7, wherein a part of the driving voltage line is in contact with the first connection member.

10. The display device of claim 1, wherein
the first data conductive layer further includes a first scan auxiliary line extending along the first direction, and
the first scan auxiliary line is electrically connected to the first scan line.

11. A display device comprising:
a substrate;
a semiconductor layer disposed on the substrate;
a gate conductive layer disposed on the semiconductor layer; and
a first data conductive layer disposed on the gate conductive layer, wherein
the gate conductive layer includes:
a first scan line, a light emitting control line, a shielding pattern layer extending along a first direction, and
a first gate electrode disposed between the first scan line and the light emitting control line in a plan view,
the first data conductive layer includes a first connecting member overlapping the first gate electrode,
the first connecting member includes a first recessed opening and a second recessed opening, and
the shielding pattern layer is disposed across the second recessed opening in the first direction.

12. The display device of claim 11, wherein the first recessed opening and the second recessed opening of the first connecting member are disposed symmetrically to each other.

13. The display device of claim 11, wherein edge portions of the shielding pattern layer in the first direction are in contact with the first connecting member, respectively.

14. The display device of claim 11, wherein the shielding pattern layer is disposed between the first gate electrode and the light emitting control line in a plan view.

15. The display device of claim 11, wherein
the first data conductive layer further includes a second connecting member,
the second connecting member is in contact with the first gate electrode at the first recessed opening of the first connecting member, and
a part of the second connecting member is in contact with the semiconductor layer.

16. The display device of claim 11, wherein
the first connecting member includes a protrusion protruding in a second direction perpendicular to the first direction, and
the protrusion of the first connecting member is in contact with the semiconductor layer.

17. The display device of claim 11, further comprising
a second data conductive layer disposed on the first data conductive layer, and
the second data conductive layer includes a driving voltage line extending along a second direction perpendicular to the first direction.

18. The display device of claim 17, wherein the driving voltage line overlaps a first recessed opening and a second recessed opening of the first connecting member.

19. The display device of claim 17, wherein
an entire region of the first recessed opening overlaps the driving voltage line, and
a partial region of the second recessed opening does not overlap the driving voltage line.

20. The display device of claim 17, wherein a part of the driving voltage line is in contact with the first connection member.
